(19) United States
(12) Patent Application Publication
(10) Pub. No.: US 2024/0321580 A1
(43) Pub. Date: Sep. 26, 2024

(54) PHOTOMASK MANUFACTURING METHOD AND SEMICONDUCTOR DEVICE MANUFACTURING METHOD USING THE SAME

(71) Applicant: Samsung Electronics Co., Ltd., Suwon-si (KR)

(72) Inventors: Dong Jin PARK, Suwon-si (KR); Sung-Yong MOON, Suwon-si (KR); Jun Young JANG, Suwon-si (KR)

(21) Appl. No.: 18/526,038

(22) Filed: Dec. 1, 2023

(30) Foreign Application Priority Data
Mar. 24, 2023 (KR) 10-2023-0038628

(51) Int. Cl. H01L 21/027; G03F 1/70; G03F 1/82; H01L 21/8234

(52) U.S. Cl. CPC H01L 21/0274; G03F 1/70; G03F 1/82; H01L 21/823431

(57) ABSTRACT

A photomask manufacturing method includes defining a main region and a dummy region based on a layout data, wherein the main region corresponds to an outer boundary surrounding functional patterns defined by the layout data and the dummy region corresponds to an empty space outside the main region, and forming a dummy pattern to fill the dummy region. The forming of the dummy pattern includes placing at least one first pattern block in the dummy region to form a first sub-region, each of the at least one first pattern block having a first area, and placing, after completing the placing of the at least one first pattern block in the dummy region, at least one second pattern block in the dummy region except the first sub-region to form a second sub-region, each of the at least one second pattern block having a second area smaller than the first area.

### CROSS-REFERENCE TO RELATED APPLICATION

This application claims priority from Korean Patent Application No. 10-2023-0038628 filed on Mar. 24, 2023 in the Korean Intellectual Property Office, and all the benefits accruing therefrom under 35 U.S.C. 119, the contents of which in its entirety are herein incorporated by reference.

### BACKGROUND

### 1. Field of the Invention

The present invention relates to a photomask manufacturing method and a semiconductor device manufacturing method using the same.

### 2. Description of the Related Art

A reticle is used in an exposure process during a semiconductor manufacturing process. The reticle may be a transparent plate having a pattern image that is transferred to a wafer coated with photoresist. All wafer circuits are ultimately patterned from the reticle. Therefore, quality of the image that may be obtained during the exposure process may be determined depending on a reticle quality.

On the other hand, as critical dimensions of semiconductor devices gradually become smaller, the exposure process using a light source with a shorter wavelength band is used in an effort for defining patterns on the wafer. As an example, a phase shift mask has been developed and used in the exposure process. A main pattern and a dummy pattern are generally formed on the wafer. The main pattern may be a gate pattern, a wiring pattern, a contact hole pattern, or the like. The dummy pattern may be formed to prevent dishing in a CMP process or to reduce a loading effect in the etching process.

### SUMMARY

Aspects of the present invention provide a photomask manufacturing method having improved efficiency.

Aspects of the present invention also provide a semiconductor device manufacturing method using the photomask manufacturing method having improved efficiency.

However, aspects of the present invention are not restricted to the one set forth herein. The above and other aspects of the present invention will become more apparent to one of ordinary skill in the art to which the present invention pertains by referencing the detailed description of the present invention given below.

According to an embodiment of the present disclosure, a photomask manufacturing method includes defining a main region and a dummy region based on a layout data, wherein the main region corresponds to an outer boundary surrounding functional patterns defined by the layout data and the dummy region corresponds to an empty space outside the main region, and forming a dummy pattern to fill the dummy region. The forming of the dummy pattern includes placing at least one first pattern block in the dummy region to form a first sub-region, each of the at least one first pattern block having a first area, and placing, after completing the placing of the at least one first pattern block in the dummy region, at least one second pattern block in the dummy region except the first sub-region to form a second sub-region, each of the at least one second pattern block having a second area smaller than the first area.

According to an embodiment of the present disclosure, a photomask manufacturing method includes defining a main region and a dummy region based on a layout data, wherein the main region corresponds to an outer boundary surrounding functional patterns defined by the layout data and the dummy region corresponds to an empty space outside the main region, and filling a dummy pattern in the dummy region. The filling of the dummy pattern in the dummy region includes placing at least one first pattern block in the dummy region to form a first sub-region, each of the at least one first pattern block corresponding to a first unit pattern block having a plurality of first unit patterns and a first number of the plurality of first unit patterns corresponding to 4^{k}, placing, after completing the placing of the at least one first pattern block in the dummy region, at least one second pattern block in the dummy region except the first sub-region to form a second sub-region, each of the at least one second pattern block corresponding to a second unit pattern block having a plurality of second unit patterns and a second number of the plurality of second unit patterns corresponding to 4^{k-1}, and placing, after completing the placing of the at least one second pattern block in the dummy region, at least one (k+1)^{th} pattern block in the dummy region except the first and second sub-regions to form a (k+1)^{th} sub-region, each of the at least one (k+1)^{th} pattern block corresponding to a (k+1)^{th} unit pattern block having a single (k+1)^{th} unit pattern, wherein k is a natural number of 2 or more, and wherein each of the first unit patterns and each of the second unit patterns are the same as the single (k+1)^{th} unit pattern in area and shape.

According to an embodiment of the present disclosure, a semiconductor device manufacturing method includes providing a substrate, forming a photomask having a dummy pattern, and aligning the photomask with the substrate to form a memory cell including a word line, a bit line and a capacitor, wherein the photomask includes a main region corresponding to the memory cell and a dummy region in which the dummy pattern is placed. The forming of the photomask includes placing at least one first pattern block in the dummy region to form a first sub-region, each of the at least one first pattern block corresponding to a first unit pattern block having a first area and a plurality of first unit patterns within a boundary of the first unit pattern block, and a first number of the plurality of first unit patterns corresponding to 4^{k}, and placing, after completing the placing of the at least one first pattern block in the dummy region except the first sub-region, at least one second pattern block in the dummy region except the first sub-region to form a second sub-region, each of the at least one second pattern block corresponding to a second unit pattern block having a second area smaller than the first area and having a plurality of second unit patterns within a boundary of the second unit pattern block, and a second number of the plurality of second unit patterns corresponding to 4^{k-1}, wherein k is a natural number of 2 or more.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary flow chart for explaining the photomask manufacturing method according to some embodiments.

FIG. 2 is a diagram for explaining a main region and a dummy region.

FIG. 3 is a diagram for explaining first to fourth patterns according to some embodiments.

FIG. 4 is an exemplary flow chart for explaining step S120 of FIG. 1 according to some embodiments.

FIG. 5 is an enlarged view of a region P of FIG. 2.

FIGS. 6 to 10 are diagrams for explaining the photomask manufacturing method according to some embodiments.

FIG. 11 is a diagram for explaining fifth to eighth patterns according to some embodiments.

FIG. 12 is an exemplary flow chart for explaining step S120 of FIG. 1 according to some other embodiments.

FIGS. 13 to 17 are diagrams for explaining a photomask manufacturing method according to some other embodiments.

FIG. 18 is a diagram for explaining first to fourth patterns according to some other embodiments.

FIG. 19 is an exemplary flow chart for explaining step S120 of FIG. 1 according to some other embodiments.

FIG. 20 is a flow chart for explaining a semiconductor device manufacturing method according to some embodiments.

FIGS. 21 to 23 are intermediate diagrams for explaining the semiconductor device manufacturing method according to some embodiments.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present invention.

A photomask manufacturing method according to some embodiments will be described below with reference to the accompanying drawings.

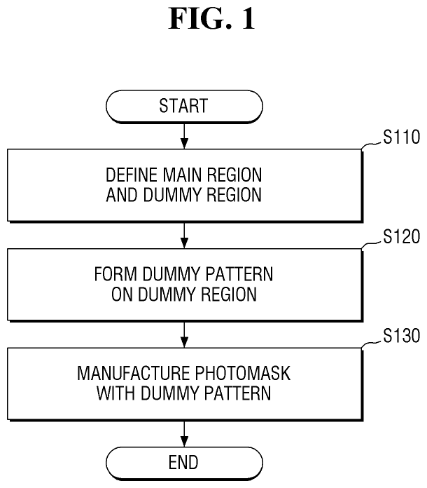

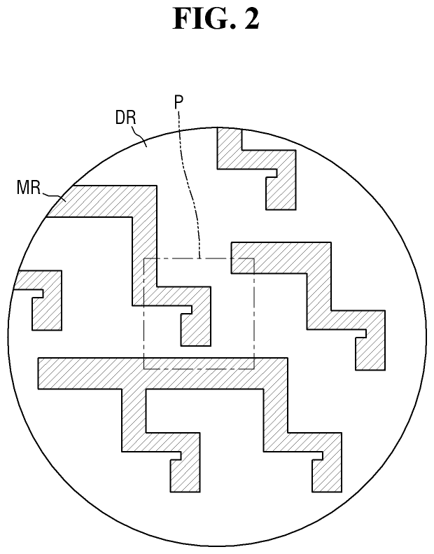

FIG. 1 is an exemplary flow chart for explaining the photomask manufacturing method according to some embodiments. FIG. 2 is a diagram for explaining a main region and a dummy region.

Referring to FIGS. 1 and 2, the photomask manufacturing method according to some embodiments may include a step of defining the main region and the dummy region (S110), a step of forming a dummy pattern on the dummy region (S120), and a step of manufacturing a photomask with the dummy pattern (S130).

In FIG. 2, a main region MR and a dummy region DR may be defined. The main region MR may be a region in which operating cell transistors are formed. For example, at least one of a dynamic random access memory (DRAM), a flash memory, a static random access memory (SRAM), a phase-change random access memory (PRAM), a resistive random access memory (RRAM), and a logic element may be formed in the main region MR. A main pattern may be formed in the main region MR. The main pattern may include, but is not limited to, a gate pattern, a metal wiring pattern, and/or a via hole pattern. The dummy region DR may be a region in which operating cell transistors are not formed.

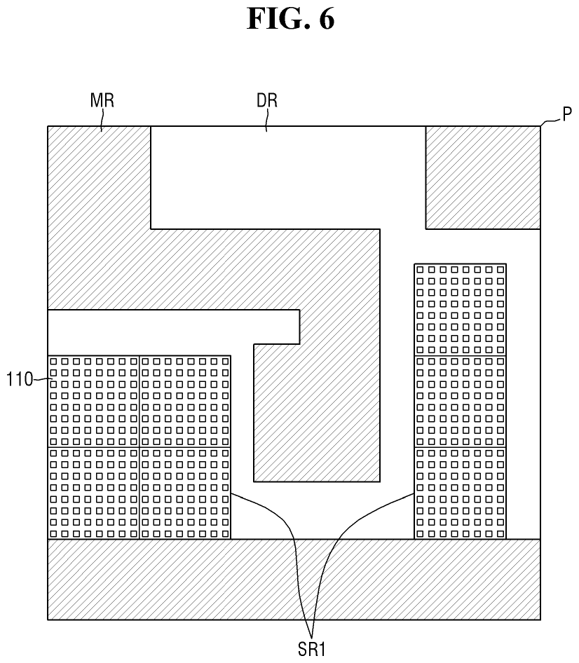

A dummy pattern may be formed on the dummy region. Formation of the dummy pattern may include a step of utilizing a fractal structure. The “fractal structure” may mean a structure in which small structures are repeated in a manner similar to an overall structure. For example, utilization of the fractal structure may mean formation of a desired pattern, using a first shape with a first size, a second shape with a second size, and/or a third shape with a third size. This will be described in detail using FIGS. 6 to 19.

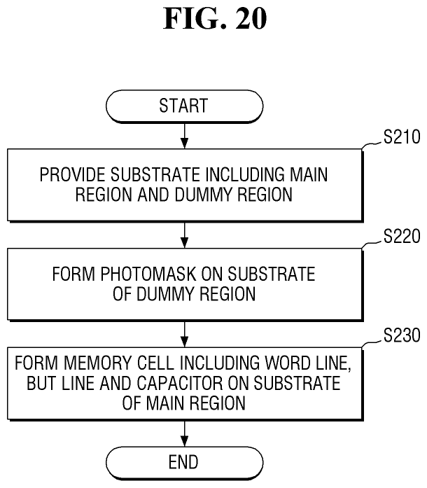

A photomask with a dummy pattern may be manufactured. In some embodiments, the dummy pattern may be formed in the dummy region DR before forming the main pattern in the main region MR. For example, the dummy pattern may be formed in the dummy region DR, and the main pattern may be formed in the main region MR. The present disclosure is not limited thereto. the main pattern may be formed in the main region MR before forming the dummy pattern in the dummy region DR. Formation of the main patterns will be described in detail using FIGS. 20 to 23.

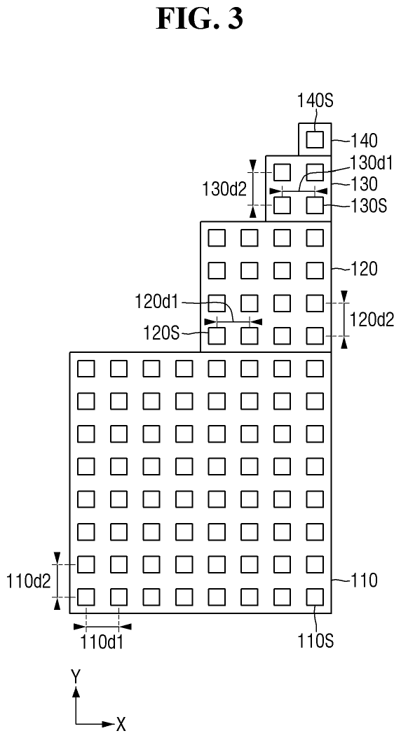

The photomask manufacturing method according to some embodiments will be described below in more detail with reference to FIGS. 3 to 10.

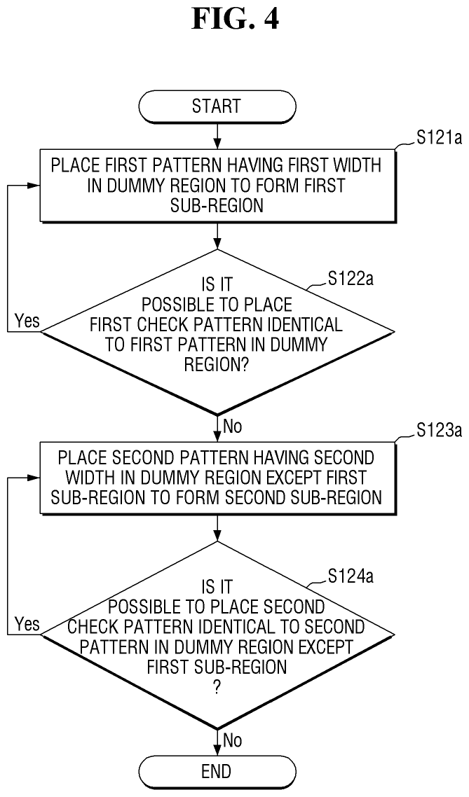

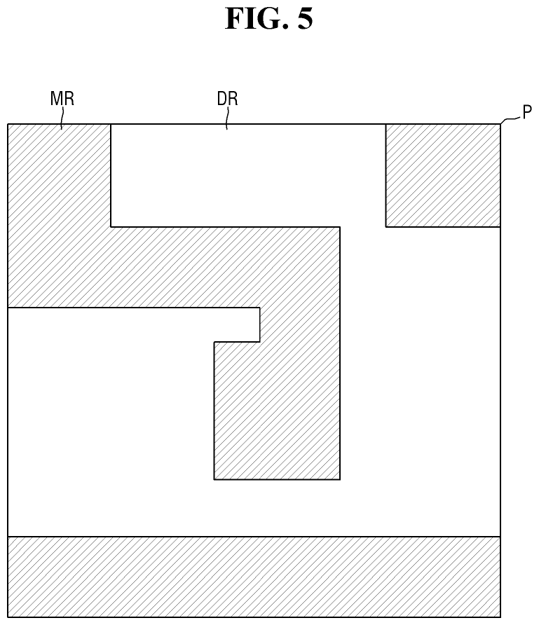

FIG. 3 is a diagram for explaining first to fourth patterns according to some embodiments. FIG. 4 is an exemplary flow chart for explaining step S120 of FIG. 1 according to some embodiments. FIG. 5 is an enlarged view of a region P of FIG. 2. FIGS. 6 to 10 are diagrams for explaining the photomask manufacturing method according to some embodiments.

Referring to FIG. 3, a first pattern 110 (i.e., a first unit pattern block), a second pattern 120 (i.e., a second unit pattern block), a third pattern 130 (i.e., a third unit pattern block), and a fourth pattern 140 (i.e., a fourth unit pattern block) may be provided. The first pattern 110, the second pattern 120, the third pattern 130, and the fourth pattern 140 may be patterns arranged in the dummy region DR to form the dummy pattern. For example, FIG. 3 shows a plurality of unit pattern block types which correspond to fractal patterns. The plurality of unit pattern block types may include the first to fourth unit pattern blocks. In FIG. 3, four unit pattern block types are disclosed. The present disclosure is not limited thereto. For example, the plurality of unit pattern block types may have two unit pattern block types or five or more unit pattern block types.

The first pattern 110 may include a plurality of first sub-patterns 110S (i.e., a plurality of first unit patterns). The plurality of first sub-patterns 110S may be placed to be spaced apart from each other at regular intervals. For example, the first sub-patterns 110S adjacent to each other in a first direction X may be spaced apart by a first horizontal distance 110d1. The first sub-patterns 110S adjacent to each other in a second direction Y may be spaced apart by a first vertical distance 110d2. In some embodiments, the first horizontal distance 110d1 and the first vertical distance 110d2 may be identical. The present disclosure, however, is not limited thereto.

In some embodiments, the first pattern 110 may be a periodic pattern. The “periodic pattern” may mean that constant patterns are arranged regularly.

In the present specification, the first direction X and the second direction Y may intersect with each other. The first direction X and the second direction Y may be substantially perpendicular to each other.

In some embodiments, 64 first sub-patterns 110S may be arranged within the first pattern 110. The 64 first sub-patterns 110S may be regularly arranged. However, the technical idea of the present invention is not limited thereto. 4ⁿ first sub-patterns 110S may be arranged in the first pattern 110, and at this time, n may be a natural number of 3 or more. In some embodiments, the first pattern 110 may have a first width or a first area. To fill the dummy region DR, the first pattern 110 may be repeatedly placed in the dummy region DR without overlapping the main region MR until the entire dummy region DR is scanned. The location of the first pattern 110 that is placed in the dummy region DR may be stored as mask data corresponding to a layout data. Locations of the 64 sub-patterns 110S may not be stored as the mask data, thereby reducing the amount of the mask data. In some embodiments, the location of the first pattern 110 and information of the unit pattern block type (e.g., the first unit pattern block) may be stored as the mask data. For example, the information of the unit pattern block type may include the size and area of the first unit pattern block, the number of the first sub-patterns 110S (e.g., 64), a first horizontal distance 110d1, or a first vertical distance 110d2. After scanning through the entire dummy region DR (i.e., after completing of placing the first pattern 110 in the dummy region DR), filling of the second pattern 120 in the dummy region DR may be initiated when a region of the dummy region DR remains unfilled with the first pattern 110.

The second pattern 120 may include a plurality of second sub-patterns 120S (i.e., a plurality of second unit patterns). The plurality of second sub-patterns 120S may be placed to be spaced apart from each other at regular intervals. For example, the second sub-patterns 120S adjacent to each other in the first direction X may be spaced apart by a second horizontal distance 120d1. The second sub-patterns 120S adjacent to each other in the second direction Y may be spaced apart by a second vertical distance 120d2. In some embodiments, the second horizontal distance 120d1 and the second vertical distance 120d2 may be identical. The present disclosure, however, is not limited thereto. The second pattern 120 may be a periodic pattern.

In some embodiments, 16 second sub-patterns 120S may be arranged inside the second pattern 120. 16 second sub-patterns 120S may be regularly arranged. However, the technical idea of the present invention is not limited thereto. 4ⁿ⁻¹ second sub-patterns 110S may be arranged inside the second pattern 120, and at this time, n may be a natural number of 3 or more.

In some embodiments, a ratio of the number of first sub-patterns 110S to the number of second sub-patterns 120S may be 4:1. For example, when the number of first sub-patterns 110S is 4ⁿ, the number of second sub-patterns 120S may be 4ⁿ⁻¹.

In some embodiments, the second pattern 120 may have a second width or a second area. The second width may be smaller than the first width of the first pattern 110. For example, a ratio of the first area of the first pattern 110 to the second area of the second pattern 120 may be 4:1. For example, a length of the first pattern 110 in the first direction X may be twice a length of the second pattern 120 in the first direction X. A length of the first pattern 110 in the second direction Y may be twice a length of the second pattern 120 in the second direction Y. Therefore, the first area of the first pattern 110 may be four times the second area of the second pattern 120.

In some embodiments, the first horizontal distance 110d1 is identical to the second horizontal distance 120d1. The first vertical distance 110d2 is identical to the second vertical distance 120d2. The interval between the first sub-patterns 110S in the first pattern 110 may be identical to the interval between the second sub-patterns 120S in the second pattern 120. To fill the dummy region DR, the second pattern 120 may be repeatedly placed in the dummy region DR without overlapping the main region MR until the entire dummy region DR is scanned. The location of the second pattern 120 that is placed in the dummy region DR may be stored as mask data corresponding to the layout data. Locations of the 16 sub-patterns 120S may not be stored as the mask data, thereby reducing the amount of the mask data. In some embodiments, the location of the second pattern 120 and information of the unit pattern block type (e.g., the second unit pattern block) may be stored as the mask data. For example, the information of the unit pattern block type may include the size and area of the second unit pattern block, the number of the second sub-patterns 120S (e.g., 16), the second horizontal distance 120d1, or the second vertical distance 120d2. After the entire dummy region DR is scanned (i.e., after completing of placing second pattern 120 in the dummy region DR), filling of the third pattern 130 in the dummy region DR may be initiated when a region of the dummy region DR remains unfilled with the second pattern 120.

The third pattern 130 may include a plurality of third sub-patterns 130S (i.e., a plurality of third unit patterns). The plurality of third sub-patterns 130S may each be placed to be spaced apart from each other at regular intervals. For example, the third sub-patterns 130S adjacent to each other in the first direction X may be spaced apart by a third horizontal distance 130d1. The third sub-patterns 130S adjacent to each other in the second direction Y may be spaced apart by a third vertical distance 130d2. In some embodiments, the third horizontal distance 130d1 and the third vertical distance 130d2 may be identical. The present disclosure, however, is not limited thereto. The third pattern 130 may be a periodic pattern.

In some embodiments, four third sub-patterns 130S may be arranged inside the third pattern 130. However, the technical idea of the present invention is not limited thereto. 4ⁿ⁻² third sub-patterns 130S may be arranged inside the third pattern 130. At this time, n may be a natural number of 3 or more.

In some embodiments, a ratio of the number of first sub-patterns 110S to the number of third sub-patterns 130S may be 4²:1. For example, when the number of first sub-patterns 110S is 4ⁿ, the number of third sub-patterns 130S may be 4ⁿ⁻². The ratio of the number of second sub-patterns 120S to the number of third sub-patterns 130S may be 4:1. For example, when the number of second sub-patterns 120S is 4ⁿ⁻¹, the number of third sub-patterns 130S may be 4ⁿ⁻².

In some embodiments, the third pattern 130 may have a third width or a third area. The third width may be smaller than the first width of the first pattern 110 and the second width of the second pattern 120. The third area may be smaller than the first area of the first pattern 110 and the second area of the second pattern 120. In some embodiments, the ratio of the first area of the first pattern 110 to the third area of the third pattern 130 may be 4²:1. For example, the length of the first pattern 110 in the first direction X may be four times the length of the third pattern 130 in the first direction X. The length of the first pattern 110 in the second direction Y may be four times the length of the third pattern 130 in the second direction Y. Therefore, the first area of the first pattern 110 may be 4² times the third area of the third pattern 130.

A ratio of the second area of the second pattern 120 to the third area of the third pattern 130 may be 4:1. For example, the length the second pattern 120 in the first direction X of may be twice the length of the third pattern 130 in the first direction X. The length of the second pattern 120 in the second direction Y may be twice the length of the third pattern 130 in the second direction Y. Therefore, the second area of the second pattern 110 may be four times the third area of the third pattern 130.

In some embodiments, the first horizontal distance 110d1, the second horizontal distance 120d1, and the third horizontal distance 130d1 may be identical to each other. The first vertical distance 110d2, the second vertical distance 120d2, and the third vertical distance 130d2 may be identical to each other. The interval of the first sub-patterns 110S in the first pattern 110, the interval of the second sub-patterns 120S in the second pattern 120, and the interval of the third sub-patterns 130S in the third pattern 130 may be identical to each other.

The fourth pattern 140 may include one fourth sub-pattern 140S. However, the embodiment is not limited thereto. The fourth pattern 140 may include a plurality of fourth sub-patterns 140S. At this time, 4ⁿ⁻³ fourth sub-patterns 140S may be arranged inside the fourth pattern 140. At this time, n may be a natural number of 3 or more.

In some embodiments, a ratio of the number of first sub-patterns 110S to the number of fourth sub-patterns 140S may be 4³:1. For example, when the number of first sub-patterns 110S is 4ⁿ, the number of fourth sub-patterns 140S may be 4ⁿ⁻³. A ratio of the number of second sub-patterns 120S to the number of fourth sub-patterns 140S may be 4²:1. For example, when the number of second sub-patterns 120S is 4ⁿ⁻¹, the number of fourth sub-patterns 140S may be 4ⁿ⁻³. A ratio of the number of third sub-patterns 130S to the number of fourth sub-patterns 140S may be 4:1. For example, when the number of third sub-patterns 130S is 4ⁿ⁻², the number of fourth sub-patterns 140S may be 4ⁿ⁻³. To fill the dummy region DR, the third pattern 130 may be repeatedly placed in the dummy region DR without overlapping a portion of the main region MR until the entire dummy region DR is scanned. The location of the third pattern 130 that is placed in the dummy region DR may be stored as the mask data corresponding to the layout data. In some embodiments, the location of the fourth pattern 120 and information of the unit pattern block type (e.g., the fourth unit pattern block) may be stored as the mask data. For example, the information of the unit pattern block type may include the size and area of the fourth unit pattern block or the number of the fourth sub-patterns 140S.

In some embodiments, the fourth pattern 140 may have a fourth width or a fourth area. The fourth width may be smaller than the first width of first pattern 110, the second width of second pattern 120, and the third width of third pattern 130. The fourth area may be smaller than the first area of first pattern 110, the second area of second pattern 120, and the third area of third pattern 130. In some embodiments, a ratio of the first area of the first pattern 110 to the fourth area of the fourth pattern 140 may be 4³:1. For example, the length of the first pattern 110 in the first direction X may be eight times the length of the fourth pattern 140 in the first direction X. The length of the first pattern 110 in the second direction Y may be eight times the length of the fourth pattern 140 in the second direction Y. Therefore, the first area of the first pattern 110 may be 4³ times the fourth area of the fourth pattern 140.

A ratio of the second area of the second pattern 120 to the fourth area of the fourth pattern 140 may be 4²:1. For example, the length of the second pattern 120 in the first direction X may be four times the length of the fourth pattern 140 in the first direction X. The length of the second pattern 120 in the second direction Y may be four times the length of the fourth pattern 140 in the second direction Y. Therefore, the second area of the second pattern 120 may be 4² times the fourth area of the fourth pattern 140.

A ratio of the third area of the third pattern 130 to the fourth area of the fourth pattern 140 may be 4:1. For example, the length of the third pattern 130 in the first direction X may be twice the length of the fourth pattern 140 in the first direction X. The length of the third pattern 130 in the second direction Y may be twice the length of the fourth pattern 140 in the second direction Y. Therefore, the second area of the second pattern 120 may be four times the fourth area of the fourth pattern 140.

The first to fourth patterns 110, 120, 130 and 140 may be sequentially placed in the dummy region DR of FIG. 2. The dummy pattern may be formed in the dummy region DR, using the first to fourth patterns 110, 120, 130 and 140.

FIG. 3 shows fractal patterns of four patterns having different widths or different areas. The present disclosure, however, is not limited thereto. For example, the number of patterns placed in the dummy region DR may be greater or smaller than four. The number of patterns placed in the dummy region DR may be changed as desired depending on the shape of the dummy region DR.

Referring to FIGS. 1, 2, and 5, a photomask manufacturing method according to some embodiments may include step S110 of defining the dummy region DR and the main region MR. The dummy region DR and the main region MR may be changed as desired depending on the product design. For example, in step S110, the main region MR and the dummy region DR may be defined based on a layout data in a data format of GDSII or OASIS, for example. The main region MR may correspond to an outer boundary surrounding functional patterns defined by the layout data and the dummy region DR may correspond to an empty space outside the main region MR. In some embodiments, the outer boundary may contact the outermost parts of the functional patterns. In some embodiments, the functional patterns may represent a portion of a circuitry such as gate electrodes of transistors and metal patterns connecting the transistors with each other. In some embodiments, the functional patterns may be transferred onto a photomask substrate which is transparent or semi-transparent substrate. For example, the functional patterns may be etched onto the photomask substrate to form a photomask corresponding to the layout data. The photomask may also be referred to as a mask or a reticle.

Referring to FIGS. 3, 4 and 6, the step (S120 of FIG. 1) of forming the dummy pattern in the dummy region may include a step (S121a) of placing the first pattern 110 having the first width or the first area in the dummy region to form a first sub-region SR1. For example, the dummy pattern may fill the dummy region DR as an anti-reflective pattern or an anti-blister pattern. A photolithography process using, for example, extreme ultraviolet (EUV) and a photomask having the dummy pattern may achieve a fine patterning of a target layer.

In FIG. 6, at least one first pattern 110 are placed in the dummy region DR. At this time, the first patterns 110 may contact each other. The first patterns 110 adjacent to each other may contact each other. The first patterns 110 may be placed to form the first sub-region SR1. The first sub-region SR1 may be placed inside the dummy region DR. The first sub-region SR1 may completely overlap the dummy region DR. The at least one first pattern 110 may also be referred to as at least one first pattern block. In some embodiments, the at least one first pattern block may be placed in the dummy region DR, and each first pattern block corresponds to a first unit pattern block having a first area in which a plurality of first unit patterns are periodically arranged at a first interval within a boundary of the first unit pattern block. The first unit pattern block may correspond to the first pattern 110 of FIG. 3.

Referring to FIGS. 4 and 6, it is possible to determine whether a first check pattern identical to the first pattern 110 may be placed in the dummy region DR except the first sub-region SR1 (S122a). In some embodiments, the first check pattern may correspond to the first unit pattern block. In some embodiments, the dummy region DR may be scanned through using the first check pattern to find a location in which the first check pattern is placed as the at least one first pattern 110. For example, the first check pattern may be sequentially placed at first to third locations of the dummy region DR. At the first location, if the first check pattern is determined as not overlapping the main region MR, the first check pattern may be placed at the first location as the at least one first pattern 110 and may move to the second location. At the second location, if the first check pattern is determined as overlapping the main region MR, the first check pattern is moved to the third position without placing the first check pattern at the second location as the at least one first patterns 110. This process of moving and placing of the first check pattern may be repeated until the entire locations of the dummy region DR are scanned.

For example, the first check pattern having the same shape as the first pattern 110 is placed on the dummy region DR. At this time, the first check pattern does not completely overlap the first sub-region SR1.

If the first check pattern includes a portion that overlaps the main region MR, it is determined that the first check pattern may not be placed in the dummy region DR except the first sub-region SR1. However, if the first check pattern does not completely overlap the main region MR, it may be determined that the first check pattern may be placed in the dummy region DR except the first sub-region SR1.

If it is determined that the first check pattern may be placed in the dummy region DR except the first sub-region SR1, the first pattern 110 may be additionally placed in the dummy region DR. If it is determined that the first check pattern may not be placed in the dummy region DR except the first sub-region SR1, at least one second pattern 120 having a second width or a second area may be placed in the dummy region DR except the first sub-region SR1. The at least one second pattern 120 may also be referred to as at least one second pattern block. In some embodiments, the at least one second pattern block may be placed in the dummy region except the first sub-region SR1, and each second pattern block corresponds to a second unit pattern block having the second area in which a plurality of second unit patterns are periodically arranged at a second interval within a boundary of the second unit pattern block. The boundary may contact the outermost parts of the plurality of second unit patterns. In some embodiments, each first unit pattern may be the same as each second unit pattern in area and size. In some embodiments, each first unit pattern may be of a square shape or a rectangular shape and may have an area with sides equal to a few nanometers. In some embodiments, the second interval may be the same as the first interval.

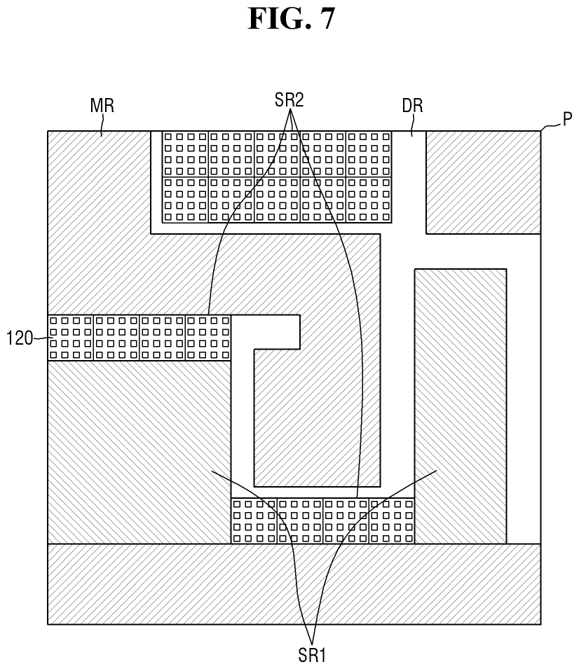

Referring to FIGS. 4 and 7, the at least one second pattern 120 may be placed in the dummy region DR except the first sub-region SR1 to form a second sub-region SR2 (S123a). A part of the first pattern 110 may contact a part of the second pattern 120. There may be no empty space between the first pattern 110 and the closet second pattern 120. The second width of the second pattern 120 may be smaller than the first width of the first pattern 110. The second width of the second pattern 120 may be ½ of the first width of the first pattern 110. The second area of the second pattern 120 may be ¼ of the first area of the first pattern 110.

It may be determined whether a second check pattern identical to the second pattern 120 may be placed in the dummy region DR except the first sub-region SR1 (S124a). In some embodiments, the second check pattern may correspond to the second unit pattern block. The second unit pattern block may correspond to the second pattern 120 of FIG. 3. In some embodiments, the dummy region DR except the first sub-region SR1 may be scanned through using the second check pattern to find a location at which the second check pattern is placed as the at least one second pattern 120. For example, the second check pattern may be sequentially placed at fourth to sixth locations of the dummy region DR. At the fourth location, if the second check pattern is determined as not overlapping the main region MR, the second check pattern may be placed at the fourth location as the at least one second pattern 120, and the second check pattern is moved to the fifth location. At the fifth location, if the second check pattern is determined as overlapping the main region MR, the second check pattern is moved to the sixth position without placing the second check pattern as the at least one second pattern 120. This process of moving and placing of the second check pattern may be repeated until the entire locations of the dummy region DR except the first sub-region SR1 are scanned.

For example, the second check pattern having the same shape as the second pattern 120 is placed on the dummy region DR. At this time, the second check pattern does not completely overlap the first and second sub-regions SR1 and SR2. When the second check pattern includes a portion that overlaps the main region MR, it is determined that the second check pattern may not be placed in the dummy region DR except the first and second sub-regions SR1 and SR2. However, when the second check pattern does not completely overlap the main region MR, it is determined that the second check pattern may be placed in the dummy region DR except the first and second sub-regions SR1 and SR2.

If it is determined that the second check pattern may be placed in the dummy region DR except the first and second sub-regions SR1 and SR2, the second pattern 120 may be additionally placed in the dummy region DR. If it is determined that the second check pattern may not be placed in the dummy region DR except the first and second sub-regions SR1 and SR2, a third pattern 130 may be placed in the dummy region DR except the first and second sub-regions SR1 and SR2.

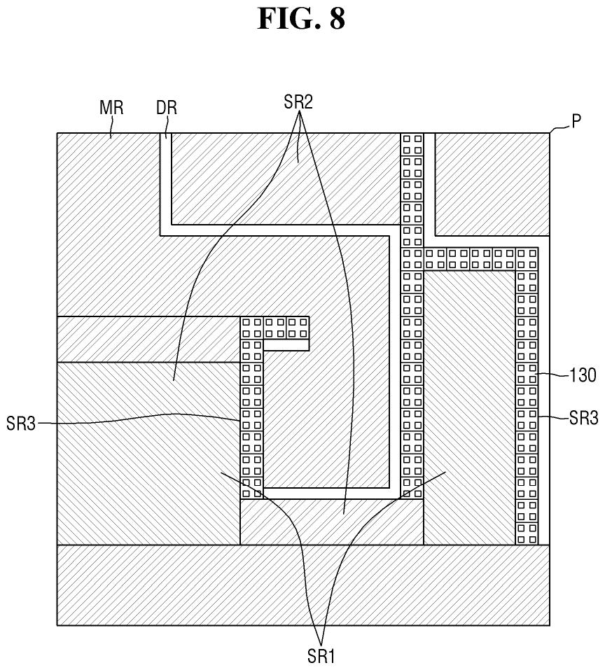

Referring to FIG. 8, at least one third pattern 130 may be placed in the dummy region DR except the first and second sub-regions SR1 and SR2. A third width of the third pattern 130 may be smaller than the first width of the first pattern 110 and the second width of the second pattern 120. The third width of the third pattern 130 may be ½ of the second width of the second pattern 120. The third area of the third pattern 130 may be ¼ of the second area of the second pattern 120. The third pattern 130 may be placed to form a third sub-region SR3. The at least one third pattern 130 may also be referred to as at least one third pattern block. In some embodiments, the at least one third pattern block may be placed in the dummy region DR except the first and second sub-regions SR1 and SR2, and each third pattern block corresponds to a third unit pattern block having a third area in which a plurality of third unit patterns are periodically arranged at a third interval within a boundary of the third unit pattern block. The boundary may contact the outermost parts of the plurality of third unit patterns. In some embodiments, each third unit pattern may be the same as each first unit pattern and/or the second unit pattern in area and shape. In some embodiments, each first unit pattern may be of a square shape or a rectangular shape and may have an area with sides equal to a few nanometers. In some embodiments, the first to third intervals may be the same as each other.

Although it is not shown, it may be determined whether the same third check pattern as the third pattern 130 may be placed in the dummy region DR except the first to second sub-regions SR1 and SR2.

For example, the third check pattern having the same shape as the third pattern 130 of FIG. 3 is placed on the dummy region DR. At this time, the third check pattern does not completely overlap the first to third sub-regions SR1, SR2 and SR3. If the third check pattern includes a portion that overlaps the main region MR, it is determined that the third check pattern may not be placed in the dummy region DR except the first to third sub-regions SR1, SR2 and SR3. However, if the third check pattern does not completely overlap the main region MR, it is determined that the third check pattern may be placed in the dummy region DR except the first to third sub-regions SR1, SR2 and SR3.

If it is determined that the third check pattern may be placed in the dummy region DR except the first to third sub-regions SR1, SR2 and SR3, the third pattern 130 may be additionally placed in the dummy region DR. If it is determined that the third check pattern may not be placed in the dummy region DR except the first to third sub-regions SR1, SR2 and SR3, a fourth pattern 140 may be placed in the dummy region DR except the first to third sub-regions SR1, SR2 and SR3.

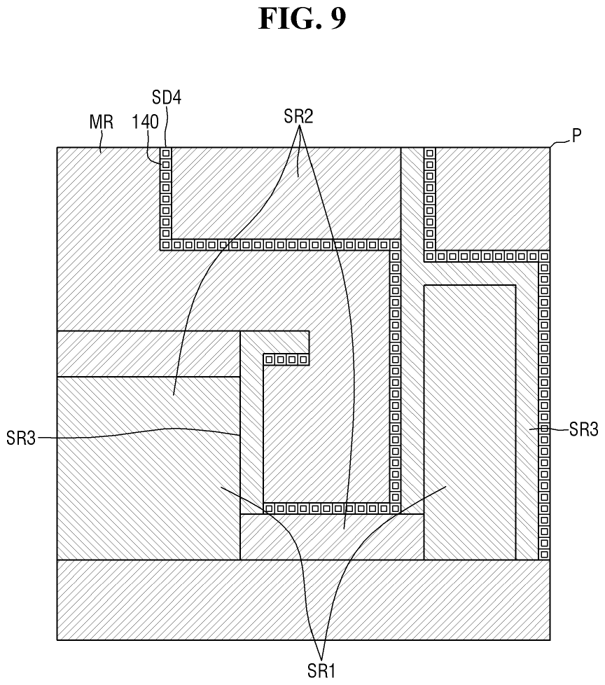

Referring to FIG. 9, at least one fourth pattern 140 may be placed in the dummy region DR except the first to third sub-regions SR1, SR2 and SR3 to form a fourth sub-region SR4. The at least one fourth pattern 140 may completely fill the dummy region DR except the first to third sub-regions SR1, SR2 and SR3. The at least one fourth pattern 140 may also be referred to as at least one fourth pattern block. In some embodiments, the at least one fourth pattern block may be placed in the dummy region DR except the first to third sub-regions SR1 to SR3, and each fourth pattern block corresponds to a fourth unit pattern block having a fourth area in which a single fourth unit pattern is disposed within a boundary of the fourth unit pattern block. The boundary may correspond to the boundary of the single fourth unit pattern. In some embodiments, the single fourth unit pattern and the first to third unit patterns may be the same as each other in area and shape. In some embodiments, each first unit pattern may be of a square shape or a rectangular shape and may have an area with sides equal to a few nanometers.

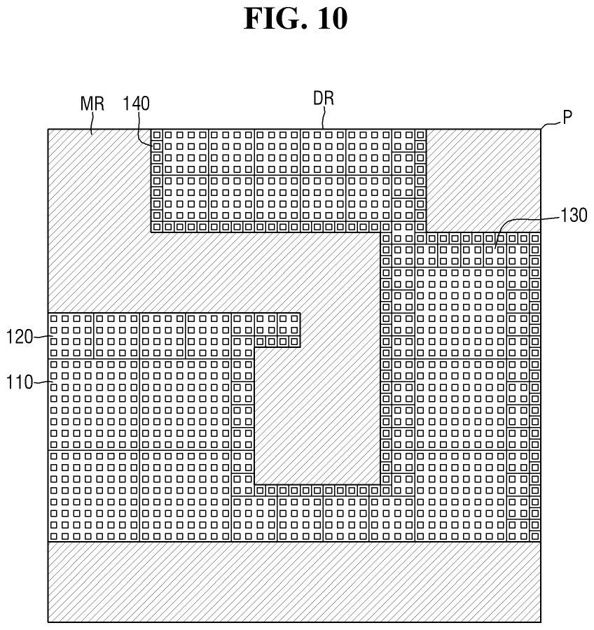

Referring to FIG. 10, the dummy region DR may be completely filled, using the first patterns 110, the second patterns 120, the third patterns 130, and the fourth patterns 140. A part of the first pattern 110 may contact a part of the second pattern 120, a part of the third pattern 130, and/or a part of the fourth pattern 140. The first sub-patterns 110S, the second sub-patterns 120S, the third sub-patterns 130S, and the fourth sub-patterns 140S may be placed to be spaced apart at regular intervals.

When using the photomask manufacturing method according to some embodiments, the time required to form the dummy pattern may be shortened. The capacity of data required to form the dummy pattern may be greatly reduced. This may be due to formation of the dummy patterns by the use of the fractal structure. Because the first pattern 110 is placed first, the second pattern 120 having a width of ½ of the first pattern is placed, the third pattern 130 having a width of ½ of the second pattern is placed, and the fourth pattern 140 having ½ of the width of the third pattern 130 is placed, the time required to form the dummy pattern can be reduced, and the capacity of data required to form the dummy pattern can be reduced.

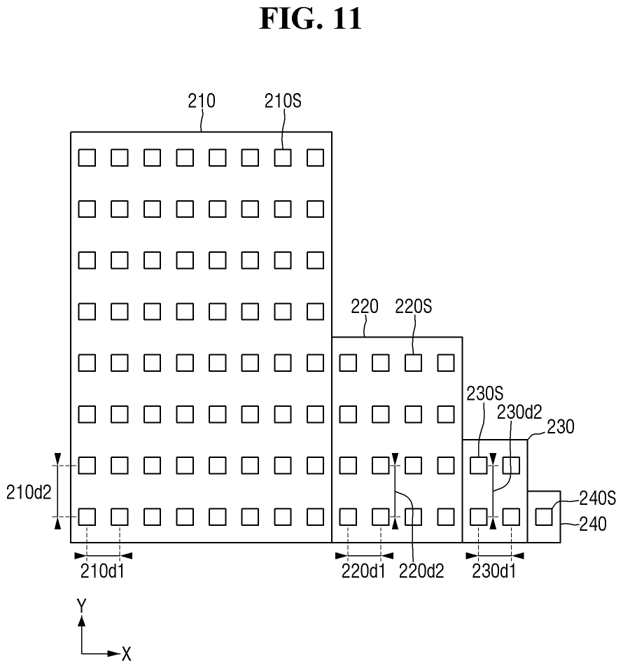

Hereinafter, a photomask manufacturing method according to other embodiments will be described with reference to FIGS. 11 to 17.

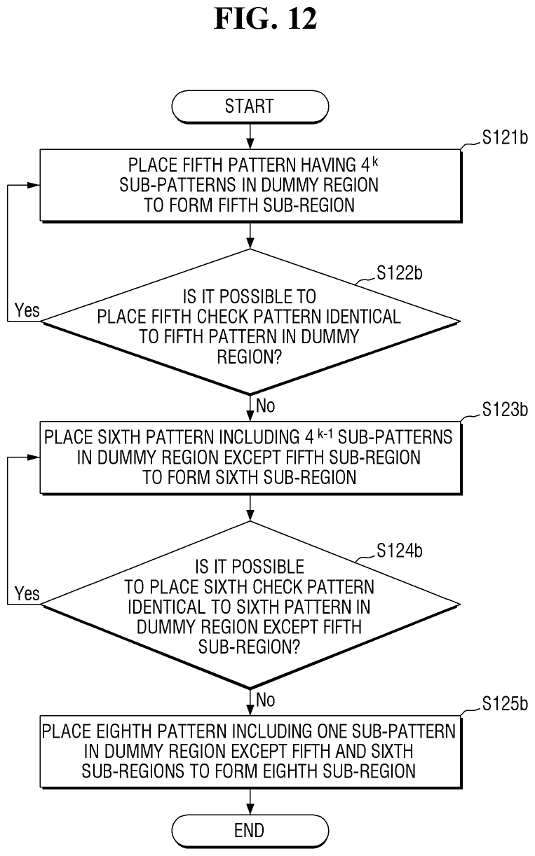

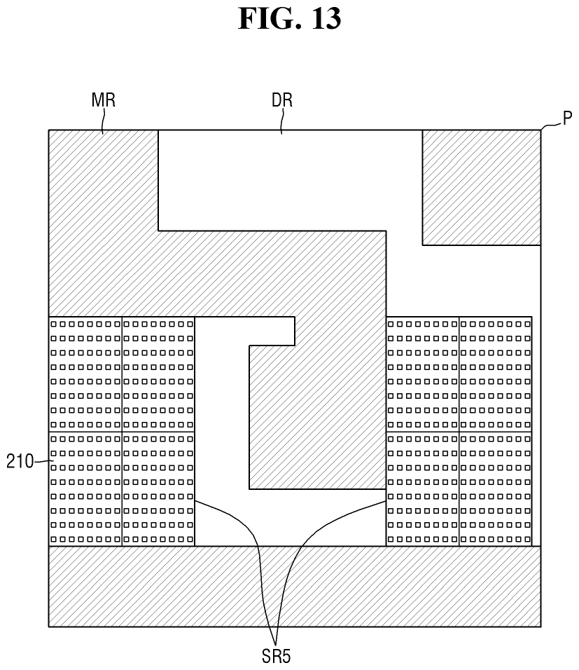

FIG. 11 is a diagram for explaining fifth to eighth patterns according to some embodiments. FIG. 12 is an exemplary flow chart for explaining step S120 of FIG. 1 according to some other embodiments. FIGS. 13 to 17 are diagrams for explaining a photomask manufacturing method according to some other embodiments. For convenience of explanation, repeated contents of those explained using FIGS. 1 to 10 will be briefly explained or omitted.

Referring to FIG. 11, a fifth pattern 210, a sixth pattern 220, a seventh pattern 230, and an eighth pattern 240 may be provided. The fifth pattern 210, the sixth pattern 220, the seventh pattern 230, and the eighth pattern 240 may be patterns placed in the dummy region DR to form the dummy patterns.

The fifth pattern 210 may include a plurality of fifth sub-patterns 210S. The plurality of fifth sub-patterns 210S may be placed to be spaced apart from each other at regular intervals. For example, the fifth sub-patterns 210S adjacent to each other in the first direction X may be spaced apart by a fifth horizontal distance 210d1. The fifth sub-patterns 210S adjacent to each other in the second direction Y may be spaced apart by a fifth vertical distance 210d2. The fifth horizontal distance 210d1 and the fifth vertical distance 210d2 may be different from each other. As an example, the fifth vertical distance 210d2 may be greater than the fifth horizontal distance 210d1. The fifth pattern 210 may have a rectangular shape in which a side length in the first direction X is smaller than a side length in the second direction Y. However, the technical idea of the present invention is not limited thereto. For example, the fifth horizontal distance 210d1 may be greater than the fifth vertical distance 510d2, unlike the shown example.

The sixth pattern 220 may include a plurality of sixth sub-patterns 220S. The plurality of sixth sub-patterns 220S may each be placed to be spaced apart from each other at regular intervals. For example, the sixth sub-patterns 220S adjacent to each other in the first direction X may be spaced apart by a sixth horizontal distance 220d1. The sixth sub-patterns 220S adjacent to each other in the second direction Y may be spaced apart by a sixth vertical distance 220d2. The sixth horizontal distance 220d1 and the sixth vertical distance 220d2 may be different from each other. As an example, the sixth vertical distance 220d2 may be greater than the sixth horizontal distance 220d1. However, the technical idea of the present invention is not limited thereto. The sixth horizontal distance 220d1 may, of course, be greater than the sixth vertical distance 220d2, unlike the shown example.

At this time, the fifth horizontal distance 210d1 may be the same as the sixth horizontal distance 220d1, and the fifth vertical distance 210d2 may be the same as the sixth vertical distance 220d2.

The seventh pattern 230 may include a plurality of seventh sub-patterns 230S. The plurality of seventh sub-patterns 220S may be placed to be spaced apart from each other at regular intervals. For example, the seventh sub-patterns 230S adjacent to each other in the first direction X may be spaced apart by a seventh horizontal distance 230dl. The seventh sub-patterns 230S adjacent to each other in the second direction Y may be spaced apart by a seventh vertical distance 230d2. The seventh horizontal distance 230d1 and the seventh vertical distance 230d2 may be different from each other. As an example, the seventh vertical distance 230d2 may be greater than the seventh horizontal distance 230d1. However, the technical idea of the present invention is not limited thereto. The seventh horizontal distance 230d1 may, of course, be greater than the seventh vertical distance 230d2, unlike the shown example.

The eighth pattern 240 may include one eighth sub-pattern 240s.

In some embodiments, 4^{k} sub-patterns may be arranged inside the fifth through eighth patterns 210, 220, 230 and 240. FIG. k is a natural number or 0. For example, 4³ fifth sub-patterns 210S may be arranged inside the fifth pattern 210. 4² sixth sub-patterns 220S may be arranged inside the sixth pattern 220. 4¹ seventh sub-patterns 230S may be arranged inside the seventh pattern 230. 4⁰ eighth sub-patterns 240S may be arranged inside the eighth pattern 240.

In some embodiments, a ratio of the number of fifth sub-patterns 210S to a number of sixth sub-patterns 220S may be 4:1. A ratio of the number of sixth sub-patterns 220S to the number of seventh sub-patterns 230S may be 4:1. A ratio of the number of seventh sub-patterns 230S to the number of eighth sub-patterns 240S may be 4:1.

In some embodiments, a ratio of the area of fifth pattern 210 to the area of sixth pattern 220 may be 4:1. A ratio of the area of sixth pattern 220 to the width of seventh pattern 230 may be 4:1. A ratio of the area of the seventh pattern 230 to the area of the eighth pattern 240 may be 4:1.

The first to fourth patterns 110, 120, 130 and 140 described using FIG. 3 and the fifth to eighth patterns 210, 220, 230 and 240 of FIG. 11 may be substantially the same except for the intervals of the sub-patterns.

Referring to FIGS. 12 and 13, the fifth pattern 210 including 4^{k} fifth sub-patterns 210S may be placed in the dummy region DR to form a fifth sub-region SR5 (S121b). At this time, k may be 3. The fifth pattern 210 may include 64 fifth sub-patterns 210S. However, the embodiment is not limited thereto. k may be a natural number of 3 or greater.

Subsequently, it may be determined whether a fifth check pattern identical to the fifth pattern 210 may be placed in the dummy region DR except the fifth sub-region SR5 (S122b). The 64 sub-patterns may also be regularly arranged inside the fifth check pattern.

If it is determined that the fifth check pattern may not be arranged in the dummy region DR except the fifth sub-region SR5, a sixth pattern 220 including 4^{k-1} sixth sub-patterns 220S may be placed in the dummy region DR except the fifth sub-region SR5.

If it is determined that the fifth check pattern may be placed in the dummy region DR except the fifth sub-region SR5, the fifth pattern 210 may be additionally placed in the dummy region DR to form the fifth sub-region SR5 (S121b).

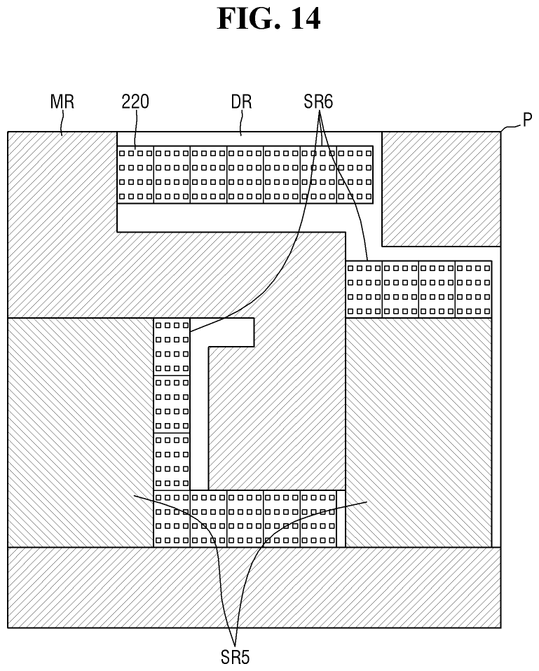

Referring to FIGS. 12 and 14, the sixth pattern 220 including 4^{k-1} sixth sub-patterns 220S may be placed in the dummy region DR except the fifth sub-region SR5 to form a sixth sub-region SR6 (S123b). In some embodiments, k may be 3. For example, the sixth pattern 220 may include 16 sixth sub-patterns 220S. However, the embodiment is not limited thereto. k may be a natural number of 3 or greater.

A part of the fifth pattern 210 may contact a part of the sixth pattern 220. There may be no empty space between the fifth pattern 210 and the closest sixth pattern 220.

Subsequently, it may be determined whether the sixth check pattern identical to the sixth pattern 220 may be placed in the dummy region DR except the fifth and sixth sub-regions SR5 and SR6 (S124b). The 16 sub-patterns may also be placed regularly inside the sixth check pattern.

When it is determined that the sixth check pattern may not be placed in the dummy region DR except the fifth and sixth sub-regions SR5 and SR6, a seventh pattern 230 including the four seventh sub-pattern 230S may be placed in the dummy region DR except the fifth and sixth sub-regions SR5 and SR6.

If it is determined that the sixth check pattern may be placed in the dummy region DR except the fifth and sixth sub-regions SR5 and SR6, the sixth pattern 220 may be additionally placed in the dummy region DR to form the sixth sub-region SR6 (S123b).

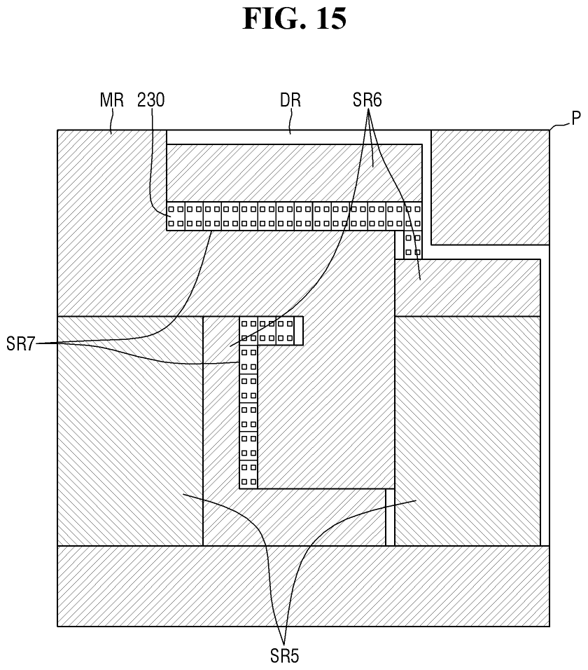

Referring to FIG. 15, the seventh pattern 230 may be placed in the dummy region DR except the fifth and sixth sub-regions SR5 and SR6 to form a seventh sub-region SR7. Similarly, it may be determined whether the seventh check pattern identical to the seventh pattern 230 may be placed in the dummy region DR except the fifth to seventh sub-regions SR5, SR6, and SR7.

If it is determined that the seventh check pattern may not be placed in the dummy region DR except the fifth to seventh sub-regions SR5, SR6, and SR7, the seventh pattern 230 including the four seven seventh sub-patterns 230S may be placed in the dummy region DR except the fifth to seventh sub-regions SR5, SR6 and SR7 to form a seventh sub-region SR7.

If it is determined that the seventh check pattern may be placed in the dummy region DR except the fifth to seventh sub-regions SR5, SR6 and SR7, the seventh pattern 230 may be additionally placed in the dummy region DR to form the seventh sub-region SR7.

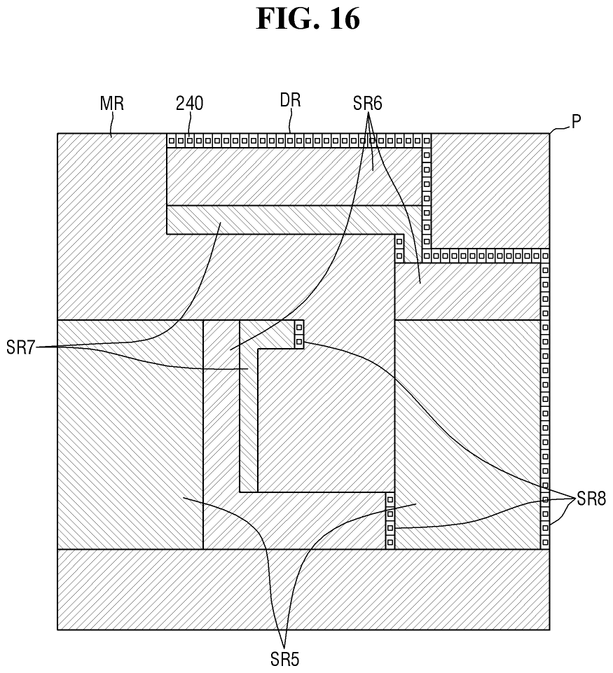

Referring to FIGS. 12 and 16, an eighth pattern 240 including one eighth sub-pattern 240S may be placed in the dummy region DR except fifth to seventh sub-regions SR5, SR6, and SR7 to form an eighth sub-region SR8 (S125b). The eighth pattern 240 may completely fill the dummy region DR except for the fifth to seventh sub-regions SR5, SR6 and SR7.

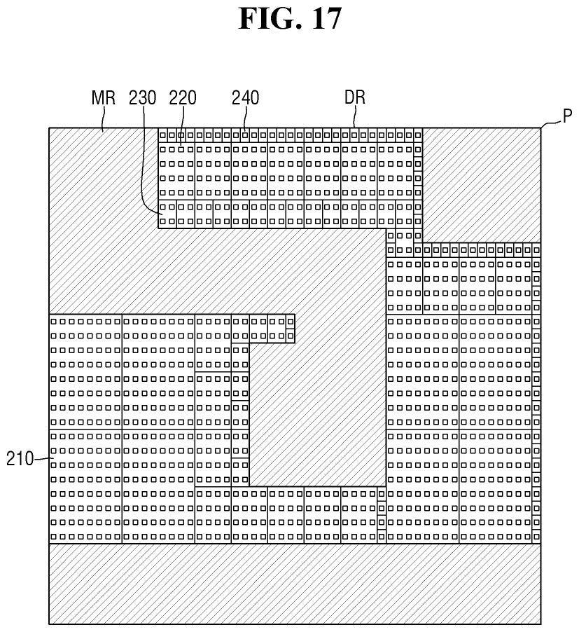

Referring to FIG. 17, the dummy region DR may be completely filled, using the fifth pattern 210, the sixth pattern 220, the seventh pattern 230 and the eighth pattern 240. The fifth sub-patterns 210S, the sixth sub-patterns 220S, the seventh sub-patterns 230S, and the eighth sub-patterns 240S may be placed to be spaced apart at regular intervals.

When using the photomask manufacturing method according to some embodiments, the time required to form the dummy pattern may be shortened. The amount of data required to form the dummy pattern may be greatly reduced. This may be due to formation of the dummy pattern by the use of fractal structure. Since the fifth pattern 210 including 64 sub-patterns is placed first, the sixth pattern 220 including the 16 sub-patterns is placed, the seventh pattern 230 including the 4 sub-patterns is placed, and the eighth pattern 240 including one sub-pattern is placed, the time required to form the dummy pattern may be reduced, and the capacity of data required to form the dummy pattern may be reduced.

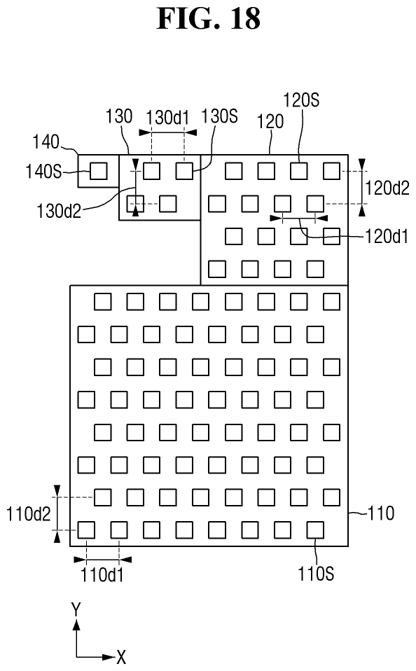

FIG. 18 is a diagram for explaining first to fourth patterns according to some other embodiments. For convenience of explanation, points that are different from those explained using FIG. 3 will be mainly explained.

Referring to FIG. 18, sub-patterns inside the pattern according to some embodiments may be offset.

For example, the first pattern 110 includes a plurality of first sub-patterns 110S. The first sub-patterns 110S adjacent to each other in the first direction X are arranged to be spaced apart by a first horizontal distance 110d1. The first sub-patterns 110S adjacent to each other in the second direction Y are arranged to be spaced apart by a first vertical distance 110d2. At this time, the centers of the first sub-patterns 110S adjacent to each other in the first direction X may be aligned in the first direction X, and the centers of the first sub-patterns 110S adjacent to each other in the second direction Y may be offset in the second direction Y. For example, the centers of the first sub-patterns 110S adjacent to each other in the second direction Y are not aligned in the second direction Y. The centers of the first sub-patterns 110S adjacent to each other in the second direction Y may be misaligned in the second direction Y. For example, the first sub-patterns 110S may be arranged in zigzags.

The second pattern 120 includes a plurality of second sub-patterns 120S. The second sub-patterns 120S adjacent to each other in the first direction X are arranged to be spaced apart by a second horizontal distance 120d1. The second sub-patterns 120S adjacent to each other in the second direction Y are arranged to be spaced apart by a second vertical distance 120d2. At this time, the centers of the second sub-patterns 120S adjacent to each other in the first direction X may be aligned in the first direction X, and the centers of the second sub-patterns 120S adjacent to each other in the second direction Y may be offset in the second direction Y. For example, the centers of second sub-patterns 120S adjacent to each other in the second direction Y are not aligned in the second direction Y. The centers of the second sub-patterns 120S adjacent to each other in the second direction Y may be misaligned in the second direction Y. For example, the second sub-patterns 120S may be arranged in zigzags.

The third pattern 130 includes a plurality of third sub-patterns 130S. The third sub-patterns 130S adjacent to each other in the first direction X are arranged to be spaced apart by a third horizontal distance 130d1. The third sub-patterns 130S adjacent to each other in the second direction Y are arranged to be spaced apart by a third vertical distance 130d2. At this time, the centers of the third sub-patterns 130S adjacent to each other in the first direction X may be aligned in the first direction X, and the centers of the third sub-patterns 130S adjacent to each other in the second direction Y may be offset in the second direction Y. For example, the centers of the third sub-patterns 130S adjacent to each other in the second direction Y are not aligned in the second direction Y. The centers of the third sub-patterns 130S adjacent to each other in the second direction Y may be misaligned in the second direction Y. For example, the third sub-patterns 130S may be arranged in zigzags.

The fourth pattern 140 may include one fourth sub-pattern 140S.

In some embodiments, the first horizontal distance 110d1, the second horizontal distance 120d1, and the third horizontal distance 130d1 are equal. The first vertical distance 110d2, the second vertical distance 120d2, and the third vertical distance 130d2 are equal. The first sub-patterns 110S, the second sub-patterns 120S, and the third sub-patterns 130S may be arranged at regular intervals.

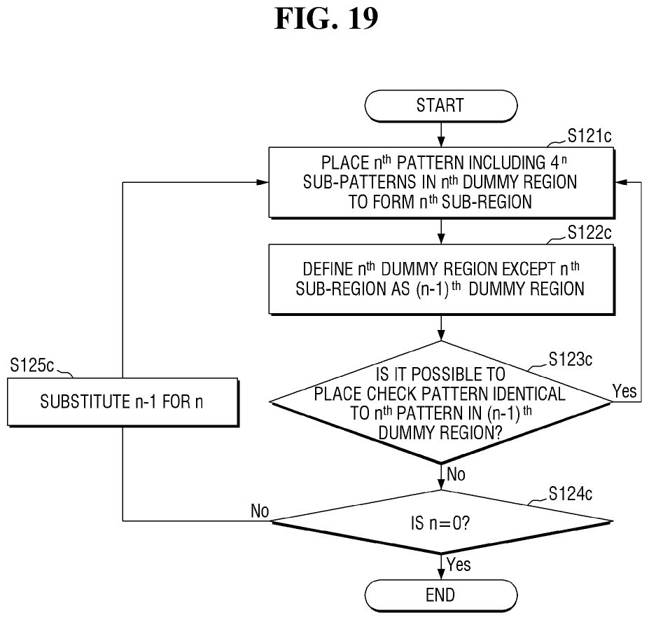

FIG. 19 is an exemplary flow chart for explaining step S120 of FIG. 1 according to some other embodiments. For reference, FIG. 19 may be a general flowchart of a photomask manufacturing method according to some embodiments.

Referring to FIG. 19, an n^{th} pattern including 4ⁿ sub-patterns is placed in an n^{th} dummy region to form an n^{th} sub-region (S121c). At this time, n may be a natural number of 3 or more. Preferably, n may be, but is not limited to, 3 or more and 10 or less. It goes without saying that n may be a natural number greater than 10.

The n^{th} dummy region except the n^{th} sub-region is defined as an (n−1)^{th} dummy region (122c). Subsequently, it is checked whether the same check pattern as the n^{th} pattern may be placed in the (n−1)^{th} dummy region (S123c).

When the check pattern is arranged in the (n−1)^{th} dummy region, if the check pattern includes a portion that overlaps the main region, it is determined that the check pattern may not be placed in the (n−1)^{th} dummy region. When the check pattern is arranged in the (n−1)^{th} dummy region, if the check pattern does not completely overlap the main region, it is determined that the check pattern may be placed in the (n−1)^{th} dummy region.

If it is determined that the check pattern may be placed in the (n−1)^{th} dummy region, the n^{th} pattern is additionally placed in the n^{th} dummy region (S121c). If it is determined that the check pattern may not be arranged in the (n−1)^{th} dummy region, it is determined whether n=0 (S124c).

If n−0, the photomask manufacturing method ends. If not n=0, n−1 is substituted for n and step S121c is performed again (S125c).

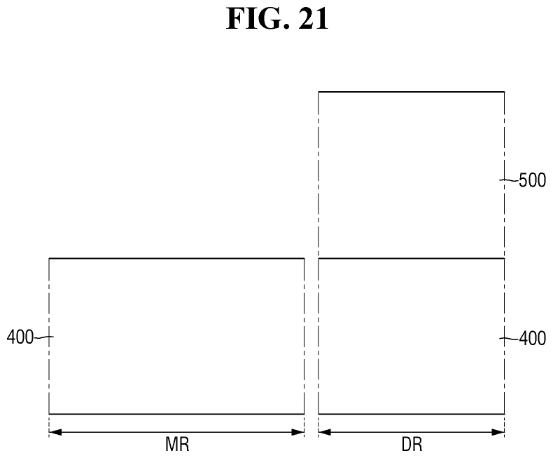

FIG. 20 is a flow chart for explaining a semiconductor device manufacturing method according to some embodiments. FIGS. 21 to 23 are intermediate diagrams for explaining the semiconductor device manufacturing method according to some embodiments.

Referring to FIGS. 20 and 21, a substrate 400 including a main region MR and a dummy region DR is provided (S210).

The substrate 400 may be, for example, a silicon single crystal substrate or an SOI (Silicon on Insulator) substrate. The present disclosure is not limited thereto. In some embodiments, the substrate 400 may include silicon germanium, silicon germanium on insulator (SGOI), indium antimonide, lead telluride, indium arsenide, indium phosphide, gallium arsenide or gallium antimonide.

A photomask 500 may be aligned with the substrate 400 of the dummy region DR (S220). The photomask 500 may cover the dummy region DR. The photomask 500 may be formed, using the photomask manufacturing method described using FIGS. 1 to 19.

Subsequently, the memory cell including a word line, a bit line, and a capacitor may be formed on the substrate 400 of the main region MR (S230). The main pattern formed in the main region MR may correspond functional patterns of a DRAM. The present disclosure, however, is not limited thereto.

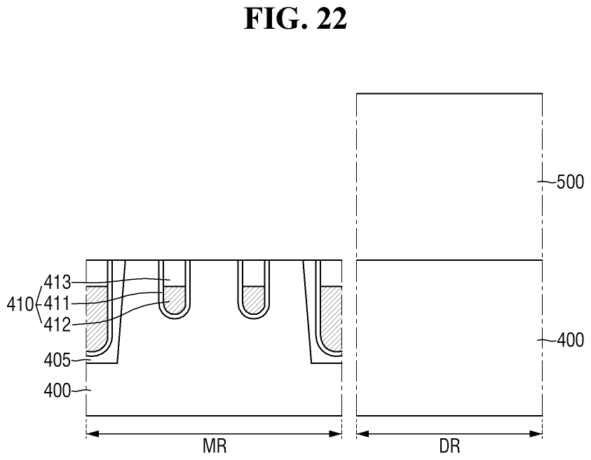

Referring to FIG. 22, a device isolation film 405 may be formed in the substrate 400 of the main region MR. The device isolation film 405 may include an insulating material. For example, the device isolation film 405 may include or may be a silicon oxide film, a silicon nitride film, a silicon oxynitride film, or a combination thereof. The present disclosure, however, is not limited thereto.

In some embodiments, the device isolation film 405 may define an active region. The active region is provided in the substrate 400 and defined by the device isolation film 405.

A word line structure 410 may then be formed in the substrate 400. The word line structure 410 may include a gate insulating film 411, a word line 412 and a gate capping film 413. The word lines 412 may be formed in the substrate 400. The word line 412 may extend in one direction inside the substrate 400.

The word line 412 may include at least one of metal, a metal alloy, a conductive metal nitride, a conductive metal carbonitride, a conductive metal carbide, a metal silicide, a doped semiconductor material, a conductive metal oxynitride, and a conductive metal oxide. The word line 412 may include, for example, at least one of TiN, TaC, TaN, TiSiN, TaSiN, TaTiN, TiAlN, TaAlN, WN, Ru, TiAl, TiAlC—N, TiAlC, TIC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx and a combination thereof.

The gate capping film 413 may be formed on the word line 412. The gate capping film 413 may include, for example, at least one of silicon nitride (SiN), silicon oxynitride (SiON), silicon oxide (SiO₂), silicon carbonitride (SiCN), silicon oxycarbonitride (SiOCN), and a combination thereof.

The gate insulating film 411 may be formed along side walls and bottom face of the word line 412 and side walls of the gate capping film 413. The gate insulating film 411 may include, for example, at least one of silicon oxide, silicon nitride, silicon oxynitride, and a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

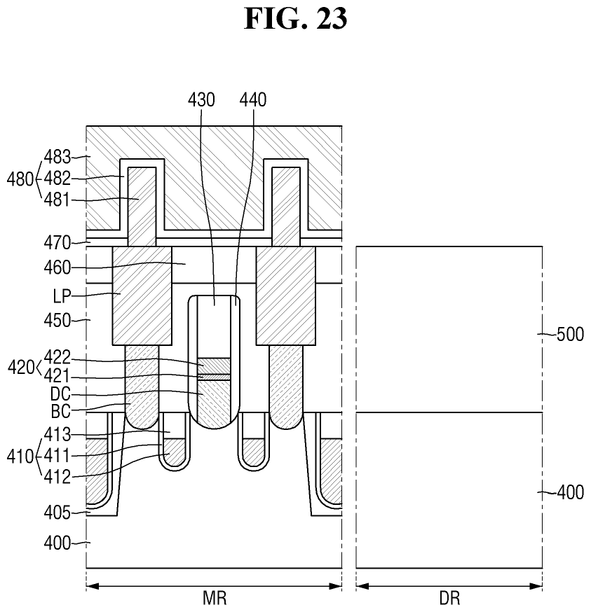

Referring to FIG. 23, a direct contact DC, a buried contact BC, a landing pad LP, a bit line 420, a fence pattern 450 and a capacitor 480 may be formed on the substrate 400.

The direct contact DC and the bit line 420 may be formed on the substrate 400. The direct contact DC may mean a contact that electrically connects the active region to the bit line 420. The direct contact DC may be formed of, for example, polysilicon doped with impurities.

The bit line 420 may be formed on the direct contact DC. The bit line 420 may include a first conductive film 421 and a second conductive film 422. Although it is not shown, the bit line 420 that does not overlap the direct contact DC may include a conductive film placed below the first conductive film 421. The first conductive film 421 may include TiSiN. The second conductive film 422 may include tungsten (W). However, the technical idea of the present invention is not limited thereto.

A bit line capping pattern 430 may be formed on the bit line 420. The bit line capping pattern 430 may be formed of silicon nitride film.

A bit line spacer 440 may be formed on side walls of the bit line 420, side walls of the direct contact DC, and side walls of the bit line capping pattern 430. The bit line spacer 440 may be a single layer as shown, but may be multi-layered unlike the shown example. For example, the bit line spacer 440 may include, but is not limited to, one of silicon oxide film, silicon nitride film, silicon oxynitride film (SiON), silicon oxycarbonitride film (SiOCN), air, and a combination thereof.

A buried contact BC may be formed on one side and the other side of the bit line 420. The buried contact BC may be connected to the substrate 400. The buried contact BC may be connected to the active region. In some embodiments, each of the active region to which the buried contact BC is connected, and the active region to which the direct contact DC is connected may be a source/drain region of a semiconductor device according to some embodiments. The buried contact BC may include at least one of impurity-doped polysilicon, a conductive silicide compound, a conductive metal nitride and metal. The buried contact BC may have island shapes that are spaced apart from each other from a planar viewpoint.

The fence pattern 450 may be formed on the substrate 400 and the device isolation film 405. The fence pattern 450 may be formed to overlap the word line 412. The fence pattern 450 may be placed between the buried contact BC and the bit line 420. The fence pattern 450 may insulate the adjacent buried contacts BC. The fence pattern 450 may be formed of an insulating material. For example, the fence pattern 450 may be formed of, but is not limited to, a silicon oxide film.

The landing pad LP may be formed on the buried contact BC. The landing pad LP may be electrically connected to the buried contact BC. The landing pad LP may include, for example, at least one of an impurity-doped semiconductor material, a conductive silicide compound, conductive metal nitride, conductive metal carbide, metal, and a metal alloy.

A pad isolation insulating film 460 may be formed on the landing pad LP and the bit line 420. For example, the pad isolation insulating film 460 may be placed on the bit line capping pattern 430. The pad isolation insulating film 460 may define a region of the landing pad LP that forms a plurality of isolation regions. The pad isolation insulating film 460 may not cover the upper face of the landing pad LP.

The pad isolation insulating film 460 may include an insulating material and electrically isolate the plurality of landing pads LP from each other. The pad isolation insulating film 460 may include, for example, at least one of a silicon oxide film, a silicon nitride film, a silicon oxynitride film, a silicon oxycarbonitride film, and a silicon carbonitride film.

An etching stop film 470 may be formed on the pad isolation insulating film 460 and the landing pad LP. The etching stop film 470 may include at least one of silicon nitride film, silicon carbonitride film, silicon boron nitride film (SiBN), silicon oxynitride film, and silicon oxycarbide film.

A capacitor 480 may be formed on the landing pad LP. The capacitor 480 may be electrically connected to the landing pad LP. A part of the capacitor 480 may be formed in the etching stop film 470. The capacitor 480 includes a capacitor lower electrode 481, a capacitor dielectric film 482, and a capacitor upper electrode 483.

The capacitor lower electrode 481 may be formed on the landing pad LP. In some embodiments, the capacitor lower electrode 481 may have a pillar shape. The present disclosure, however, is not limited thereto. For example, the capacitor lower electrode 481 may have a cylindrical shape. The capacitor dielectric film 482 is formed on the capacitor lower electrode 481. The capacitor dielectric film 482 may be formed along the profile of the capacitor lower electrode 481. The capacitor upper electrode 483 is formed on the capacitor dielectric film 482. The capacitor upper electrode 483 may cover the outer side walls of the capacitor lower electrode 481.

The capacitor lower electrode 481 and the capacitor upper electrode 483 may each include, for example, but are not limited to, a doped semiconductor material, a conductive metal nitride (e.g., titanium nitride, tantalum nitride, niobium nitride, tungsten nitride, etc.), a metal (e.g., ruthenium, iridium, titanium, or tantalum), and a conductive metal oxide (e.g., iridium oxide or niobium oxide).

The capacitor dielectric film 482 may include, for example, but is not limited to, one of silicon oxide, silicon nitride, silicon oxynitride, high dielectric constant material, and a combination thereof. In the semiconductor device according to some embodiments, the capacitor dielectric film 482 may include a layered film structure in which zirconium oxide, aluminum oxide, and zirconium oxide are sequentially stacked. In the semiconductor device according to some embodiments, the capacitor dielectric film 482 may include a dielectric film including hafnium (Hf). In the semiconductor device according to some embodiments, the capacitor dielectric film 482 may have a stacked film structure of a ferroelectric material film and a paraelectric material film.

In concluding the detailed description, those skilled in the art will appreciate that many variations and modifications may be made to the embodiments without substantially departing from the principles of the present disclosure. Therefore, the disclosed embodiments of the disclosure are used in a generic and descriptive sense only and not for purposes of limitation.

What is claimed is:

1. A photomask manufacturing method comprising:
defining a main region and a dummy region based on a layout data, wherein the main region corresponds to an outer boundary surrounding functional patterns defined by the layout data and the dummy region corresponds to an empty space outside the main region; and
forming a dummy pattern to fill the dummy region,
wherein the forming of the dummy pattern includes:
placing at least one first pattern block in the dummy region to form a first sub-region, each of the at least one first pattern block having a first area, and
placing, after completing the placing of the at least one first pattern block in the dummy region, at least one second pattern block in the dummy region except the first sub-region to form a second sub-region, each of the at least one second pattern block having a second area smaller than the first area.

2. The photomask manufacturing method of claim 1,
wherein each of the at least one first pattern block corresponds to a first unit pattern block having a plurality of first unit patterns that are periodically arranged at a first interval within a boundary of the first unit pattern block, and
wherein each of the at least one second pattern block corresponds to a second unit pattern block having a plurality of second unit patterns that are periodically arranged at a second interval within a boundary of the second unit pattern block.

3. The photomask manufacturing method of claim 2, further comprising:
storing locations of the at least one first and second pattern blocks as mask data.

4. The photomask manufacturing method of claim 3, further comprising:
storing information on a unit pattern type of each of the at least one first and second pattern blocks placed in the dummy region as the mask data,
wherein the unit pattern type may include a plurality of unit pattern blocks corresponding to fractal patterns, the plurality of unit pattern blocks including the first unit pattern block and the second unit pattern block, and
wherein the information on the unit pattern type includes a number of a plurality of unit patterns of each of the at least one first and second pattern blocks or an interval between two adjacent unit patterns among the plurality of unit patterns.

5. The photomask manufacturing method of claim 4, further comprising:
patterning a photomask substrate using the mask data to form a photomask corresponding to the layout data.

6. The photomask manufacturing method of claim 1,
wherein a ratio of the first area to the second area is 4^{k}:1, and
wherein k is a natural number of 1 or more.

7. The photomask manufacturing method of claim 1,
wherein the placing of the at least one first pattern block includes:
moving a first check pattern block having the first area at a first position within the dummy region;
determining whether the first check pattern block overlaps the main region;
placing the first check pattern block at the first position as one of the at least one first pattern block in response to the first check pattern block determined as not overlapping the main region; and
moving the first check pattern block to a second position within the dummy region without placing the first check pattern block at the first position in response to the first check pattern block determined as overlapping the main region.

8. The photomask manufacturing method of claim 7,
wherein the placing of the at least one first pattern block further includes:
determining whether the dummy region is entirely scanned using the first check pattern block; and
initiating the placing of the at least one second pattern block in response to the dummy region determined as entirely scanned.

9. The photomask manufacturing method of claim 1, further comprising:
placing at least one third pattern block in the dummy region except the first sub-region and the second sub-region to form a third sub-region, each of the at least one third pattern block having a third area smaller than the second area.

10. The photomask manufacturing method of claim 9,
wherein the placing of the at least one second pattern block further includes:
moving a second check pattern block having the second area at a third position within the dummy region except the first sub-region;
determining whether the second check pattern block overlaps the main region;
placing the second check pattern block at the third position as one of the at least one second pattern block in response to the second check pattern block determined as not overlapping the main region;
moving the second check pattern block to a fourth position within the dummy region except the first sub-region without placing the second check pattern block at the third position in response to the second check pattern block determined as overlapping the main region;
determining whether the dummy region except the first sub-region is entirely scanned using the second check pattern block; and
initiating the placing of the at least one third pattern block in response to the dummy region except the first sub-region determined as entirely scanned using the second check pattern block.

11. The photomask manufacturing method of claim 2,
wherein the first interval is the same as the second interval.

12. The photomask manufacturing method of claim 11,
wherein each of the first unit pattern block and the second unit pattern block is of a square shape,
wherein a ratio of the number of the plurality of first unit patterns to the number of the plurality of second unit patterns is 4^{k}:1, and
wherein k is a natural number of 1 or more.

13. A photomask manufacturing method comprising:
defining a main region and a dummy region based on a layout data, wherein the main region corresponds to an outer boundary surrounding functional patterns defined by the layout data and the dummy region corresponds to an empty space outside the main region; and
filling a dummy pattern in the dummy region,
wherein the filling of the dummy pattern in the dummy region includes:
placing at least one first pattern block in the dummy region to form a first sub-region, each of the at least one first pattern block corresponding to a first unit pattern block having a plurality of first unit patterns and a first number of the plurality of first unit patterns corresponding to 4^{k},
placing, after completing the placing of the at least one first pattern block in the dummy region, at least one second pattern block in the dummy region except the first sub-region to form a second sub-region, each of the at least one second pattern block corresponding to a second unit pattern block having a plurality of second unit patterns and a second number of the plurality of second unit patterns corresponding to 4^{k-1}, and
placing, after completing the placing of the at least one second pattern block in the dummy region, at least one (k+1)^{th} pattern block in the dummy region except the first and second sub-regions to form a (k+1)^{th} sub-region, each of the at least one (k+1)^{th} pattern block corresponding to a (k+1)^{th} unit pattern block having a single (k+1)^{th} unit pattern,
wherein k is a natural number of 2 or more, and
wherein each of the first unit patterns and each of the second unit patterns are the same as the single (k+1)^{th} unit pattern in area and shape.

14. The photomask manufacturing method of claim 13,
wherein a ratio of the first number to the second number is 4:1.

15. The photomask manufacturing method of claim 13,
wherein a ratio of an area of the first unit pattern block to an area of the second unit pattern block is 4:1.

16. The photomask manufacturing method of claim 13,
wherein a part of the at least one first pattern block contacts a part of the at least one second pattern block.

17. The photomask manufacturing method of claim 13,
wherein the functional patterns correspond to gate electrodes of operating cell transistors.

18. The photomask manufacturing method of claim 13,
wherein the plurality of first unit patterns are periodically arranged at a first interval within a boundary of the first unit pattern block,
wherein the plurality of second unit patterns are periodically arranged at a second interval within a boundary of the second unit pattern block, and
wherein the first interval is the same as the second interval.

19. A semiconductor device manufacturing method comprising:
providing a substrate;
forming a photomask having a dummy pattern; and
aligning the photomask with the substrate to form a memory cell including a word line, a bit line and a capacitor,
wherein the photomask includes a main region corresponding to the memory cell and a dummy region in which the dummy pattern is placed,
wherein the forming of the photomask includes:
placing at least one first pattern block in the dummy region to form a first sub-region, each of the at least one first pattern block corresponding to a first unit pattern block having a first area and a plurality of first unit patterns within a boundary of the first unit pattern block and a first number of the plurality of first unit patterns corresponding to 4^{k}, and
placing, after completing the placing of the at least one first pattern block in the dummy region except the first sub-region, at least one second pattern block in the dummy region except the first sub-region to form a second sub-region, each of the at least one second pattern block corresponding to a second unit pattern block having a second area smaller than the first area and having a plurality of second unit patterns within a boundary of the second unit pattern block, and a second number of the plurality of second unit patterns corresponding to 4^{k-1}, and
wherein k is a natural number of 2 or more.

20. The semiconductor device manufacturing method of claim 19, further comprising:
placing, after completing the placing of the at least one second pattern block in the dummy region, at least one (k+1)^{th} pattern block in the dummy region except the first and second sub-regions to form a (k+1)^{th} sub-region, each of the at least one (k+1)^{th} pattern block corresponding to a (k+1)^{th} unit pattern block having a single (k+1)^{th} unit pattern,
